(19) United States
(12) Patent Application Publication
(10) Pub. No.: US 2009/0229519 A1
(43) Pub. Date: Sep. 17, 2009

(54) APPARATUS FOR MANUFACTURING SEMICONDUCTOR THIN FILM

(76) Inventor: Hiroaki Saitoh, Shizuoka (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/097,882

(22) PCT Filed: Dec. 20, 2006
(86) PCT No.: PCT/JP2006/325372

§ 371 Date: Jun. 18, 2008

(30) Foreign Application Priority Data
Dec. 21, 2005 (JP) 2005-368173

(51) Int. Cl. C23C 16/00

(52) U.S. Cl. 118/722; 118/728

(57) ABSTRACT

The present invention provides an apparatus for manufacturing a semiconductor thin film that is capable of manufacturing an even thin film with substantially no adhesion of impurities, and is capable of improving in-plane evenness of a grown thin film. The invention is an apparatus for manufacturing a semiconductor thin film includes a reaction tube 12, a susceptor 20 disposed in the reaction tube 12, and a negative pressure generator, the negative pressure generator applying a negative pressure to a substrate 22A placed on the susceptor 20 to hold the substrate, and the substrate 22A is placed so that an angle of a normal line to a crystal growth face of the substrate 22A to a vertical downward direction is less than 180°.

### TECHNICAL FIELD

The present invention relates to an apparatus for manufacturing a semiconductor thin film that manufactures a silicon carbide semiconductor, more particularly a semiconductor thin film manufacturing apparatus that forms a semiconductor thin film on a substrate by epitaxial growth.

### BACKGROUND ART

Silicon carbide (SiC) semiconductors, for example, having excellent heat resistance and mechanical strength, have been attracting attention for such reasons as their use as a material in blue light-emitting diodes and the like, and their application to electric elements having high power and low loss due to the demand for energy saving through high pressure resistance and low ion resistivity. An SiC semiconductor is formed by depositing an SiC thin film on an SiC substrate. As a means of depositing an SiC thin film on a substrate to form an SiC semiconductor, for example, epitaxial growth of SiC can be utilized.

The SiC thin film is deposited on the substrate by epitaxial growth in which raw material gases containing H₂ gas, SiH₄ gas and C₃H₈ gas are reacted with each other on a heated SiC wafer surface. At this time, in order to grow the SiC thin film in a uniform manner, it is important that a flow of raw material gases over the SiC wafer is even, and also that the raw material gases are evenly mixed and that heat is evenly transferred to the substrate.

Based on this perspective, a CVD apparatus that can form a uniform thin film by forming a gas flow that is parallel to the substrate has been proposed (see, for example, Japanese Patent Application Laid-Open (JP-A) No. 2002-252176). According to this CVD apparatus, it is possible to form a gas flow parallel to the surface of the substrate by regulating a gas flow that has passed a heating element on which the substrate is disposed.

However, even in the aforementioned CVD apparatus or the like, there are cases whereby uniformity in the film thickness and electric characteristics of the SiC thin film cannot be ensured due to reasons such as the existence of regions where raw material gases remain and the mixing of the raw material gases being uneven. In addition, temperature distribution on the substrate may become uneven for such reasons as the mixing of the raw material gases being uneven. Further, since raw material gases are decomposed at an upstream side (gas supply side), and a rate of growth at this side is lowered compared with a downstream side (gas exhaust side), it is necessary to make a supply rate of raw material gases uniform by reducing an opening diameter to increase a flow rate of raw material gases, toward the downstream portion.

In addition, impurities such as a reaction product of SiC or dirt may adhere to an inner wall of a heating element that heats an SiC wafer or an inner wall of the apparatus. Such impurities may easily come off from the inner wall due to such reasons as a high amount of gas flow at the time of SiC growth, which is as high as several liters/min to several tens of liters/min, or repetition of vacuuming and gas charging at the time of conveying a wafer. Consequently, these impurities may be scattered in a reaction tube and mixed in with raw material gases to adhere to or mix into an SiC wafer surface or an SiC layer, thereby impairing the functional capability of the resultant SiC semiconductor.

The heating element is usually disposed in the interior of the reaction tube via a heat insulating member made of a material having porosity such as glass wool which is a graphite material. However, impurities are often adsorbed even onto the heat insulating member, and a portion of the heat insulating member may come off and become an impurity.

As a means of growing a crystal while preventing adhesion of impurities such as those described above, a chemical vapor deposition apparatus that holds a substrate in such a manner that a main surface thereof on which a crystal is grown faces downward, has been proposed (see, for example, JP-A No. 9-82649). However, in this apparatus, as the edge of a substrate is held with a susceptor, regions where a thin film does not form occur. In addition, due to unevenness in the in-plane temperature of the substrate, in-plane uniformity may decrease.

### DISCLOSURE OF THE INVENTION

### Problems to be Solved by the Invention

The object of the present invention is to solve the aforementioned problems. That is, one object of the invention is to provide an apparatus for manufacturing a semiconductor thin film capable of forming an even thin film that is substantially free from adhesion of impurities, and capable of improving in-plane evenness of a grown thin film.

### Means to Solve the Problems

An apparatus for manufacturing a semiconductor thin film of the present invention includes a reaction tube, a susceptor disposed in the inside of the reaction tube, and a negative pressure generator that applies a negative pressure to a substrate deposited on the susceptor to hold the substrate, wherein the substrate is placed so that an angle of a normal line to a crystal growth face of the substrate to a vertical downward direction is less than 180°.

The semiconductor thin film manufacturing apparatus of the invention includes a negative pressure generator that applies a negative pressure to a substrate held onto a susceptor, in order to hold the substrate on the upper side. By holding (placing) a growth face of the substrate by means of the negative pressure generator so that an angle of a normal line to a crystal growth face of the substrate to a vertical downward direction is less than 180° (for example, in a vertical direction or in a horizontal direction), adhesion of impurities due to falling of impurities can be prevented. In addition, adhesion of impurities such as reaction products or dirt caused by a flow of a raw material gas or a carrying gas can also be prevented. Since the region to which a negative pressure is applied by the negative pressure generator is positioned at a surface onto which a thin film may not be formed, an even film can be formed on a surface for thin film formation. Further, as compared with the cases where a substrate is held onto a susceptor with a holder, the semiconductor thin film manufacturing apparatus of the invention, in which substrates are held in close contact with the susceptor, can provide even temperature within a substrate surface. As a result, in-plane evenness of a grown thin film can be improved.

In the susceptor, a through hole that penetrates the susceptor and a communicating part by which a part of the through hole is in communication with a position to which a substrate is placed. It is preferable to hold the substrate by distributing a carrier gas via the through hole to generate a negative pressure in the communicating part by a negative pressure generator.

Various types of means can be applied as the negative pressure generator. One preferable embodiment of the semiconductor thin film manufacturing apparatus of the invention is a means that generates a force to attract a substrate by distributing a carrier gas in a through hole to generate a negative pressure at a communicating part. In the aforementioned means that distributes a carrier gas, a circulating system in which a carrier gas that has passed a through hole is supplied to the through hole again can be applied. This system enables effective utilization of the carrier gas, and great advantages in terms of energy and environment can be achieved.

The through hole preferably has a venturi structure in which the diameter thereof decreases from an upstream side in a direction of a carrier gas flow toward the communicating part, and increases from the communicating part toward a downstream side in a direction of the carrier gas flow.

With a structure in which a pathway for a carrier gas flow is narrowed at the communicating part in the through hole, the flow rate of the carrier gas at the communicating part can be increased (venturi effect). As a result, the negative pressure at the communicating part can be even increased and the substrate can be held more stably.

### Effect of the Invention

According to the present invention, an apparatus for manufacturing a semiconductor thin film that can form an even thin film with substantially no adhesion of impurities, and can improve in-plane evenness of a grown thin film, can be provided.

### BRIEF DESCRIPTION OF THE DRAWINGS

FIG. 1 is a partial cross-sectional view illustrating an outline of one embodiment of the semiconductor thin film manufacturing apparatus of the present invention.

FIG. 2 is a perspective view of a susceptor shown in FIG. 1.

FIG. 3 is a partial cross-sectional view illustrating an outline of another embodiment of the semiconductor thin film manufacturing apparatus of the invention.

FIG. 4 is a cross-sectional view illustrating an aspect of holding a substrate in a semiconductor thin film manufacturing apparatus of Example.

FIG. 5 is a cross-sectional view illustrating an aspect of holding a substrate in a semiconductor thin film manufacturing apparatus of Comparative Example.

FIG. 6 is a diagram illustrating an angle formed by a normal line to a crystal growth face of a substrate and a plumb line.

### BEST MODE FOR CARRYING OUT THE INVENTION

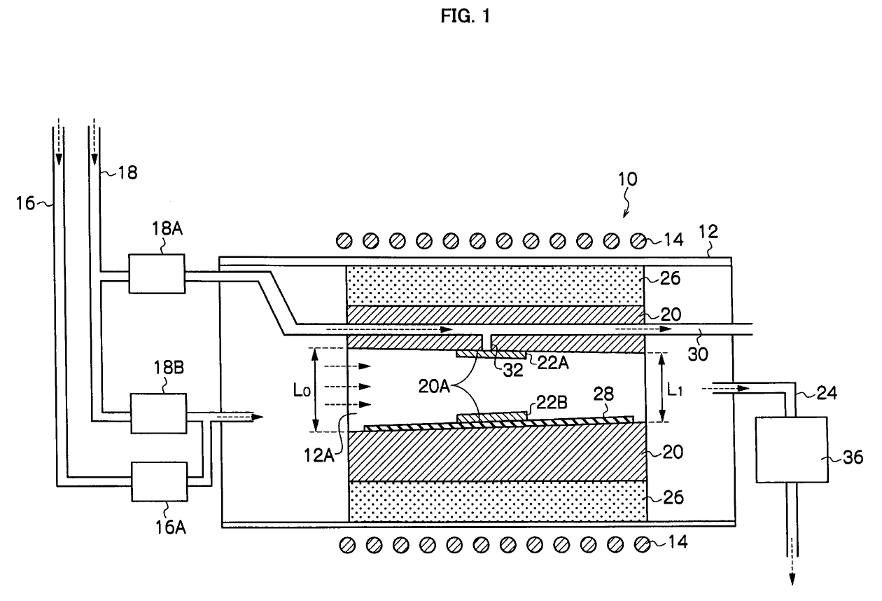

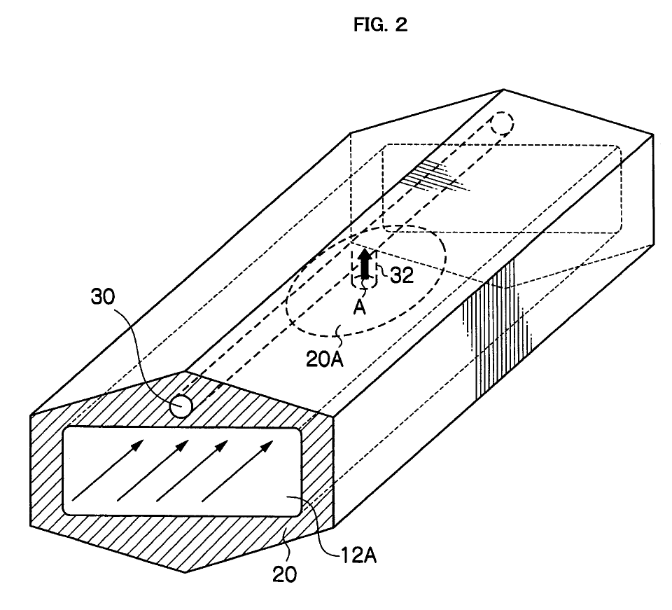

The semiconductor thin film manufacturing apparatus of the present invention will be illustrated by referring to FIG. 1 and FIG. 2. FIG. 1 is a partial cross-sectional view showing an embodiment of the semiconductor thin film manufacturing apparatus. In FIG. 1, the semiconductor thin film manufacturing apparatus 10 has a reaction tube 12, an RF coil 14 disposed on the outer side thereof, a raw material supply tube 16 that distributes raw material gases to a reaction chamber 12A in the reaction tube 12, a carrier gas supply tube 18 that supplies a carrier gas, an exhaust tube 24, and a vacuum pump 36. A thermal insulating member 26 and a susceptor 20 are provided at the inside of the reaction tube 12 in this order. Holding parts 20A that hold substrates 22A and 22B are provided at an upper part and a lower part in a vertical direction of the susceptor 20. In the susceptor 20, a through hole 30 that penetrates through the susceptor 20 is provided, and a communicating part 32 through which a part of the through hole 30 communicates with the holding part 20A is provided.

When a carrier gas is distributed in the through hole 30 while the substrate 22A is held, gas in the communicating part 32 is suctioned in a direction indicated by arrow A (see FIG. 2), thereby the pressure is reduced to generate a negative pressure. By means of this negative pressure, the substrate 22A is tightly fixed to the susceptor 20.

The substrate 22A before distributing a carrier gas in the through hole 30 is preferably temporarily fixed with a holding means. The diameter of the through hole 30 is preferably from 5 mm to 20 mm, and is more preferably from 5 mm to 10 mm. The diameter of the communicating part 32 is preferably from 5 mm to 20 mm, and is more preferably from 5 mm to 10 mm.

The holding part 20A is positioned at an upper part in a vertical direction (an upper side of the reaction chamber 12A), and two or more of those may be provided in the rest of the region. Herein, the “upper part in a vertical direction” refers to a part at a position that is higher than the bottom of the reaction chamber 12A. When the holding part 20A is also provided on a lateral side of the reaction chamber 12A, it is preferable that a negative pressure generator is provided for each of the holding parts 20A so that the substrate will not detach from the susceptor. The substrate 22A is placed so that an angle of a normal line to a crystal growth face of the substrate 22A to a vertical downward direction is less than 180°.

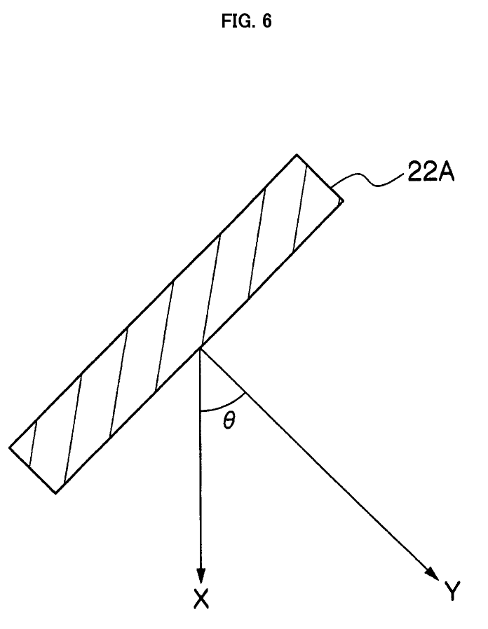

As shown in FIG. 6, the angle θ formed by a normal line to a crystal growth face of the substrate 22A (Y) and a line in a vertical downward direction (X) is preferably 90° or less (90° is more preferable). Herein, the “angle of a normal line to a crystal growth face to a vertical downward direction” refers to an angle which is smaller.

As shown in FIG. 1, in the reaction chamber 12A, raw material gases that have been introduced react at the surfaces of substrates 22A and 22B, and therefore thin films are deposited on the surfaces of the substrates 22A and 22B.

Next, a structure of the susceptor will be illustrated by referring to FIG. 2. FIG. 2 is a perspective view extracting only the susceptor 20. As shown in FIG. 2, for example, the susceptor 20 has a hexagonal cross-sectional shape and has a hollow part having a rectangular shape. This hollow part in the susceptor 20 corresponds to the reaction chamber 12A to which raw material gases are distributed. The wall thickness of the susceptor 20 is, for example, preferably from about 10 mm to about 30 nm. The shape of the susceptor is not limited to the embodiment shown in FIG. 2, and may be designed to be in a plate shape or the like, as appropriate.

The susceptor 20 is preferably formed from a graphite member coated with silicon carbide. At an upper part in a vertical direction of the susceptor 20 is provided the holding part 20A, where the substrate 22A is held by contacting the holding part 20A, and the substrate 22A is heated.

The susceptor 20 is designed to generate heat by means of induction heating of an RF coil 14 disposed outside the reaction tube 12, as shown in FIG. 1, and to heat the substrate indirectly. The RF coil 14 generates a high frequency magnetic flux and induces an eddy current in the susceptor 20, thereby heating the susceptor 20 by means of Joule heat generated by the eddy current. The temperature of the substrate heated by the susceptor 20 is preferably 1300° C. or higher. Particularly, in the case of growing an SiC thin film, the substrate 20A (and 20B) may be heated by the susceptor 20 to a temperature of preferably 1300° C. or higher, more preferably from about 1400° C. to about 2000° C. The heating temperature of the susceptor 20 is controlled by a controlling means (not shown) based on the surface temperatures of the susceptor 20 and the substrate.

When two kinds of raw material gases are used, these gases may be mixed and supplied from a raw material supplying tube 16, or may be supplied from separate raw material supplying tubes to the reaction chamber 12A. The carrier gas supplying tube 18 has a branched structure in order to supply a carrier gas to the reaction chamber 12A and the through hole 30, respectively. The raw material supplying tube 16 and the carrier gas supplying tube 18 is provided with MFC 16A, and 18A and 18B, respectively, so that supply amounts of the gases can be regulated.

In the case of forming an SiC thin film, C₃H₈ (propane) and SiH₄ (silane) are used as raw material gases. In this case, a H₂ gas can be used as a carrier gas to be supplied with the raw material gases. An SiC wafer (SiC substrate) can be preferably used as a substrate.

If necessary, a mixing chamber may be provided between the supplying tubes (i.e., the raw material supplying tube 16 and the carrier gas supplying tube 18) and the reaction chamber 12A. In the mixing chamber, a mixing shower plate having pores and a diffusion shower plate having pores are disposed. The raw material gas and the carrier gas supplied into the mixing chamber are mixed in order to have an even distribution of concentration, by passing through the pores in the mixing shower plate. The diameter and the number of the pores provided in the mixing shower plate can be determined in view of the type of raw material of the raw material gas, the degree of mixing, and the like.

The thermal insulating member 26 insulates the reaction tube 12 from the heat of the susceptor 20, and is preferably formed from glass wool which is a graphite material. The thermal insulating member 26 is disposed so as to be in tightly contact with the inner wall of the reaction tube 12, and the susceptor 22 is fixed on the inner wall of the thermal insulating member 26.

The thickness of substrates 22A and 22B may be appropriately determined depending on purposes and, in the present embodiment, is preferably around 400 μm. The conveyance tray 28 on which the substrate 22B is placed is preferably formed from a polycrystalline SiC member.

The exhaust tube 24 is provided with a vacuum pump 36, and is constructed so that growth under reduced pressure can be carried out, and the raw material gas in the reaction tube 12 can be discharged from the apparatus.

In the following, a process of forming a semiconductor thin film using the semiconductor thin film manufacturing apparatus of the invention will be illustrated by taking the case of forming an SiC semiconductor as an example. First, H₂ gas, SiH₄ gas and C₃H₈ gas are supplied to the reaction chamber 12A from the supplying tubes . The ratio of the supplied H₂ gas, SiH₄ gas and C₃H₈ gas here is approximately 12000/2/3 (=H₂/SiH₄/C₃H₈) by volume.

When the mixing chamber is provided between the supplying tubes and the reaction chamber 12A, respective gases (raw material gases) are mixed with each other upon passing through the pores in the mixing shower plate, and are then diffused upon passing through the pores in the diffusion shower plate and supplied to the reaction chamber 12A. The raw material gases are sufficiently mixed with the mixing shower plate and the diffusion shower plate so that the mixture has an even distribution of concentration.

The raw material gas that has been supplied to the reaction chamber 12A and reached the vicinity of the susceptor 20 is also heated by the susceptor 20. The raw material gas which has entered the reaction chamber 12A are heated to about 1500° C. when passing through a pathway formed on the side of a surface of the substrate, and are reacted on the substrate 24. As a result, SiC is deposited on the substrate to form an SiC thin film. Thereafter, the raw material gases which have passed over the substrates 22A and 22B are discharged from the apparatus via the exhaust tube 24 and the vacuum pump 26.

MFC16A, 18A and 18B provided in the supplying tubes are controlled by a controlling means such as CPU and the like (not shown), respectively, and the flow rate and pressure of the raw material gas in the reaction chamber 12A are regulated by the controlling means.

The process of forming an SiC semiconductor usually includes a step of introducing a carrier gas and an etching gas prior to the introduction of raw material gas, and carrying out etching of a substrate surface. The SiC substrate at this time is preferably heated so that a temperature at the surface thereof is from around 1300° C. to around 1600° C. Examples of the carrier gas include H₂ gas, and examples of the etching gas include hydrogen chloride and H₂ gas.

According to the semiconductor thin film manufacturing apparatus of the present invention, the pathway for the raw material gas is formed below the substrate 22A. Therefore, the substrate surface to which a thin film is formed is constantly oriented downward in a gravity force direction. Consequently, adhesion of reaction products or impurities such as broken pieces of thermal insulating materials to a surface for forming a thin film of the substrate 22A or the thin film itself can be prevented. In addition, since the surface to be formed with an SiC thin film of the substrate 22A is oriented downward in a gravity force direction, the surface is exposed to an ascending heat flow, and both of heating efficacy at high temperature and uniformity in the temperature gradient are excellent. Moreover, the temperature gradient of the substrate 22A can be uniformized.

In addition, since there is very little region in the substrate for being held with a holder, the yield of thin film growth can be improved. Further, since no gap is formed between the substrate and the susceptor, the thin film is not deposited on the backside of the substrate and the backside of the substrate does not have to be re-polished. The construction in which a carrier gas is supplied to a through hole to hold a substrate by means of a negative pressure is also cost effective, since new installation of instruments such as a vacuum pump to suction the substrate is not necessary.

The semiconductor thin film manufacturing apparatus of the invention can be modified in various ways, based on the above-described construction.

For example, in the reaction chamber 12A shown in FIG. 1, the height of a raw material gas exhaust port L₁ is preferably smaller than the height of a raw material gas supply port L₀.

When the height of the raw material gas exhaust port L₁ is smaller than the height of the raw material gas supply port L₀, the flow rate of the raw material gas at the exhaust side can be increased. Accordingly, the supply amount of the raw material gas at the exhaust side of the reaction chamber 12A can be reduced, thereby counterbalancing the difference in the growth rates of SiC thin films at the raw material gas supply side and at the exhaust side, and improving uniformity in the growth rate of SiC thin films.

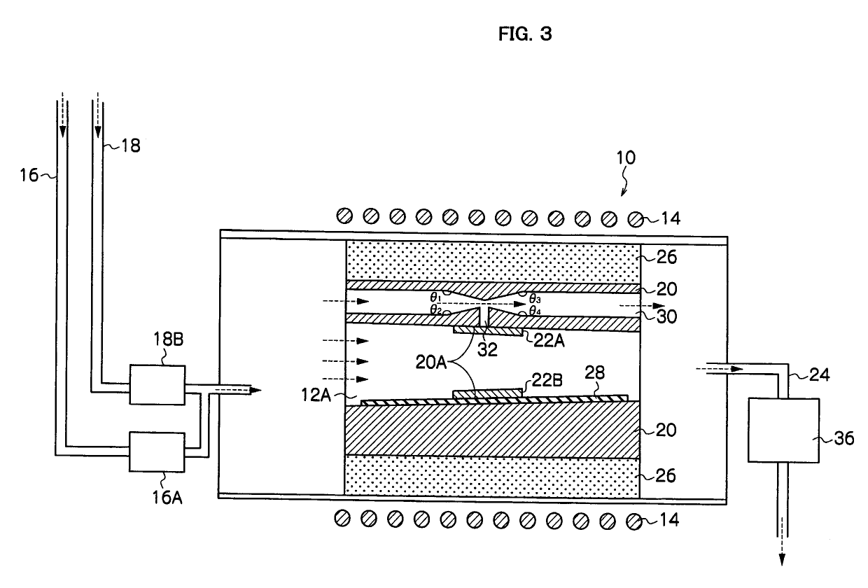

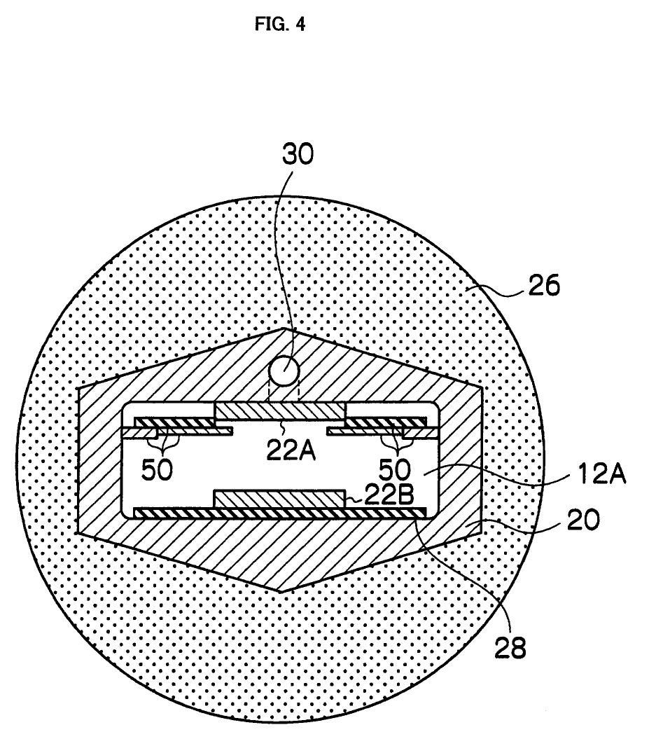

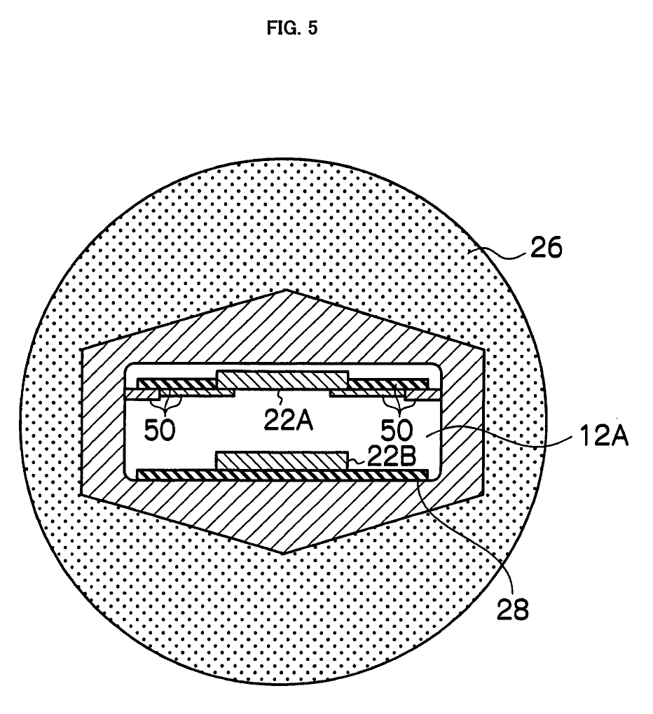

In addition, as shown in FIG. 3, a venturi structure may be adopted in which the diameter of the thorough hole 30 decreases from an upstream side in a direction of the carrier gas flow toward the communicating part 32A, and increases from the communicating part 32 toward a downstream side in a direction of the carrier gas flow. In FIG. 3, the same symbols as those of FIG. 1 exert the same functions as those in the case of FIG. 1, and illustration thereof will be omitted (the same will also apply in FIG. 4 and FIG. 5 described later).

By adopting such a form that pathway for the carrier gas is narrowed at the communicating part of the through hole, the flow rate of the carrier gas at the communicating part can be increased. As a result, a negative pressure at the communicating part is increased, and a substrate can be held more stably.

Inclination angles θ₁ to θ₄ indicating amounts of inclination of the venturi structure in FIG. 3 are preferably from 1° to 30°, more preferably from 5° to 10°, respectively.

In addition, as shown in FIG. 3, the carrier gas supply tube 18 and the raw material supply tube 16 may be combined into one supply tube in midstream to supply both of the carrier gas and the raw material gas to the reaction chamber 12A and the through hole 30. In this case, since the raw material gas is distributed also to the through hole, a thin film may be formed on a portion of the backside of the substrate 22A through the communicating part 32. However, since the pressure at the communicating part 32 is reduced, the amount of the thin film formed is small and the film is not formed on the entire surface of the substrate, as is the case with previous apparatus. Therefore productivity is not affected.

Effective utilization of the carrier gas and the raw material gas can be achieved by adopting the aforementioned structure in which the carrier gas and the raw material gas are distributed in combination, and also adopting a system in which gases discharged from the apparatus by a vacuum pump are used again.

The disclosure of Japanese Patent Application No. 2005-368173 is incorporated herein by reference in its entirety. In addition, all publications, patent applications and technical specifications described in the present description are incorporated herein by reference to the same extent as that of the case where incorporation of individual publications, patent applications, and technical specifications by reference is specifically and individually described.

### EXAMPLE 1

Formation of an SiC epitaxial thin film on a substrate was conducted using a semiconductor thin film manufacturing apparatus shown in FIG. 1. The substrate was held by distributing a carrier gas (hydrogen gas: 100 sccm) in a through hole 30 (diameter: 8 mm) while temporarily holding the substrate by a holding member 50, as shown in FIG. 4 illustrating a cross-sectional view of the reaction tube 12. The diameter of a communicating part was 8 mm.

The substrate used was a 4H-SiC wafer with a 8° off (0001) Si face. Epitaxial growth was performed by chemical vapor deposition (CVD method). The apparatus used was a horizontal hot wall-type CVD apparatus. Other growth conditions and results are shown in the following Table 1. As seen from Table 1, falling of foreign matters onto the substrate placed on the upper side and deposition of a thin film to the back surface of the substrate were not observed, and in-plane evenness was favorable. The number of defects and the presence or absence of thin film growth on the backside were determined with an optical microscope and with naked eye.

### EXAMPLE 2

Formation of an SiC epitaxial thin film on a substrate was conducted using a semiconductor thin film manufacturing apparatus equipped with a similar susceptor to that used in Example 1, except that a through hole had a venturi structure as shown in FIG. 3. Angles θ₁, θ₂, θ₃ and θ₄ were 8°, respectively. The diameters of both ends of the through hole were 8 mm, respectively. Other growth conditions and results are shown in the following Table 1. As seen from Table 1, falling of foreign matters onto the substrate placed on the upper side and deposition of a thin film to the back surface of the substrate were not observed, and in-plane evenness was favorable.

### COMPARATIVE EXAMPLE

Formation of an SiC epitaxial thin film on a substrate was conducted using a semiconductor thin film manufacturing apparatus shown in FIG. 1, except that the substrate was fixed with a holding member and no through hole was formed, as shown in FIG. 5 illustrating a cross-sectional view of the reaction tube. Conditions of the substrate used and the like were the same as those in Example 1. Other main growth conditions and results are shown in the following Table 1. As seen from Table 1, no falling of foreign matters onto the upper side of the substrate was observed, but a thin film was deposited on the back surface of the substrate. In addition, in-plane evenness was on a low level as compared with those observed in Examples.

TABLE 1

| | Example 1 | | Example 2 | | Comparative example | |
|---|---|---|---|---|---|---|
| | Upper | Lower | Upper | Lower | Upper | Lower |
| | substrate | substrate | substrate | substrate | substrate | substrate |
| Hydrogen carrier gas | 25 | 25 | 25 | 25 | 25 | 15 |
| supply amount (slm) | | | | | | |
| Silane raw material gas | 10 | 10 | 10 | 10 | 10 | 10 |
| supply amount (sccm) | | | | | | |
| Propane raw material gas | 5 | 5 | 5 | 5 | 5 | 5 |
| supply amount (sccm) | | | | | | |
| Growth rate (μm/Hr) | 8 | 8 | 8 | 8 | 8 | 8 |
| In-plane evenness of | 2.0 | 1.1 | 1.9 | 1.1 | 4.3 | 1.2 |
| grown thin film | | | | | | |
| (deviation/average) (%) | | | | | | |
| Substrate size | 1 inch | 1 inch | 1 inch | 1 inch | 1 inch | 1 inch |
| Defects due to foreign | 0 | 2 | 0 | 2 | 0 | 3 |
| matters in thin film | | | | | | |
| (number/wafer) | | | | | | |
| Thin film growth on | Absent | Absent | Absent | Absent | Present | Absent |
| backside of substrate | | | | | | |

As seen from the above Table 1, in-plane evenness in Comparative Example was on a low level. Unevenness in a temperature within the substrate surface is considered to be a cause for this result. In addition, since a substrate edge was held with a holding member in Comparative Example, thin film was not formed at the holding part, and growth of thin film on the backside of the substrate was observed. On the other hand, in each of Examples 1 and 2, no falling of foreign matters on the substrate placed on the upper side was observed, no thin film was deposited on the backside of the substrate, and in-plane evenness was favorable.

### EXPLANATION OF SYMBOLS

10—Semiconductor thin film manufacturing apparatus
12—Reaction tube
12A—Reaction chamber
14—RF coil
16—Raw material supplying tube
18—Gas supplying tube
16A, 18A, 18B—MFC
20—Susceptor
20A—holding part
22A and 22B—Substrates
24—Exhaust tube
26—Heat insulating member
28—Conveyance tray
30—Through hole
32—Communicating part

1. An apparatus for manufacturing a semiconductor thin film comprising a reaction tube, a susceptor disposed in the reaction tube, and a negative pressure generator, the negative pressure generator applying a negative pressure to a substrate placed on the susceptor to hold the substrate,
wherein the substrate is placed so that an angle of a normal line to a crystal growth face of the substrate to a vertical downward direction is less than 180°.

2. The apparatus for manufacturing a semiconductor thin film according to claim 1, wherein the negative pressure generator is a through hole that penetrates through the susceptor, and a communicating part by which a part of the through hole communicates with a holding part of the substrate is formed, and a negative pressure is generated at the communicating part to hold the substrate by distributing a carrier gas through the through hole.

3. The apparatus for manufacturing a semiconductor thin film according to claim 2, wherein the through hole has a venturi structure in which a diameter of the through hole decreases from an upstream side in a direction of the carrier gas flow toward the communicating part, and increases from the communicating part toward a downstream side in a direction of the carrier gas flow.

4. The apparatus for manufacturing a semiconductor thin film according to claim 1, wherein the substrate is placed so that the angle of the normal line to the crystal growth face of the substrate to the vertical downward direction is 90° or less.

5. The apparatus for manufacturing a semiconductor thin film according to claim 3, wherein an angle of inclination that indicates an amount of inclination in the venturi structure is from 1° to 30°.

6. The apparatus for manufacturing a semiconductor thin film according to claim 5, wherein the angle of inclination that indicates the amount of inclination in the venturi structure is from 5° to 10°.

7. The apparatus for manufacturing a semiconductor thin film according to claim 1, further comprising a mixing chamber.
